(19) United States
(12) Patent Application Publication
(10) Pub. No.: US 2008/0213995 A1
(43) Pub. Date: Sep. 4, 2008

(54) Ultrasonic electropolishing of conductive material

(76) Inventors: Tatyana N. Andryushchenko, Portland, OR (US); Radek P. Chalupa, Hillsboro, OR (US); Anne E. Miller, Portland, OR (US); Lei Jiang, Camas, WA (US)

Correspondence Address: TROP PRUNER & HU, PC, 1616 S. VOSS ROAD, SUITE 750, HOUSTON, TX, 77057-2631, US

(21) Appl. No.: 11/713,215

(22) Filed: Mar. 2, 2007

(51) Int. Cl. H01L 21/44; C25D 17/00

(52) U.S. Cl. 438/653; 204/194; 257/E21.04

(57) ABSTRACT

In one embodiment, the present invention includes a method for forming a dielectric layer on a semiconductor wafer and patterning at least one opening in the dielectric layer, depositing a barrier layer over the dielectric layer, depositing a conductive layer over the barrier layer, and electropolishing the conductive layer while ultrasonically agitating the semiconductor wafer until a predetermined amount of the conductive layer remains over the barrier layer. Other embodiments are described and claimed.

### BACKGROUND

In fabricating microelectronic devices, one process used to form interconnects is known as a “damascene process.” In a typical damascene process, a photoresist material is patterned on a dielectric material and the dielectric material is etched through the patterning to form a hole or a trench or a via (generically an opening). The photoresist material is then removed and the opening is then filled with a conductive material.

A barrier layer is typically deposited on the dielectric material within the opening to prevent diffusion of the conductive material. As an example, when copper is used as the conductive material diffusion can occur into adjacent layers, thus, a diffusion layer is needed to prevent such diffusion. Additionally, a seed layer is deposited on the barrier layer. The seed layer acts as an activation site for formation of the conductive layer.

The resulting structure is planarized, usually by a technique called chemical mechanical polish (CMP) or by an etching process, which removes the conductive material that is not within the opening, from the surface of the dielectric material, to form the interconnect. However, for a low-dielectric constant (k) dielectric, the mechanical integrity of the dielectric layer may be weakened by the process. Thus, the conventional process used to planarize the conductive material has a high tendency of damaging the dielectric layer.

### BRIEF DESCRIPTION OF THE DRAWINGS

FIG. 1 is a flow diagram of a method in accordance with an embodiment of the present invention

FIG. 2 is a block diagram of a semiconductor tool in accordance with an embodiment of the present invention.

FIG. 3 is a cross section view of a semiconductor wafer in accordance with an embodiment of the present invention.

### DETAILED DESCRIPTION

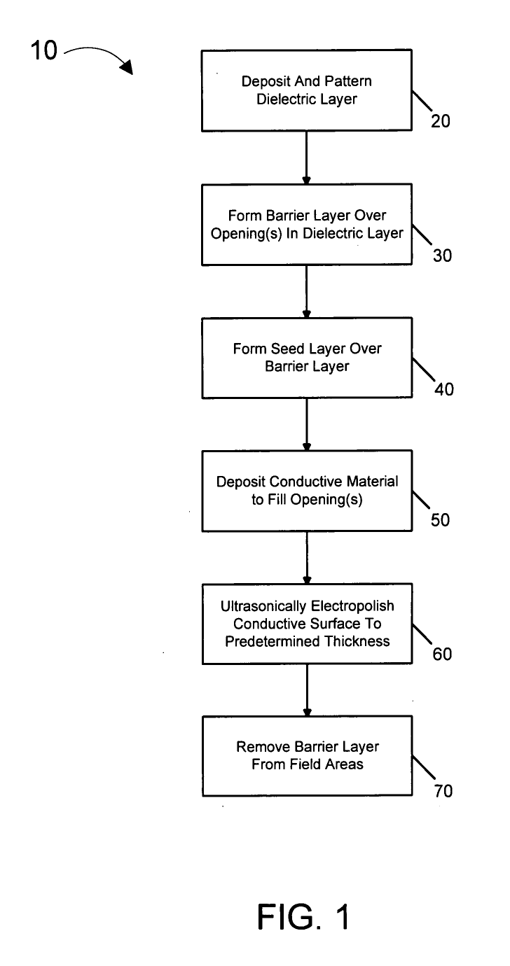

FIG. 1 illustrates an exemplary method 10 of forming an interconnect in accordance with an embodiment of the present invention. At block 20, a dielectric layer is formed on a substrate and may be patterned as desired. For example, the dielectric layer can be a low-k dielectric layer, with one or more openings formed using, e.g., a damascene process. The dielectric layer may include, but is not limited to, silicon oxide, silicon nitride, carbon doped oxide, fluorinated silicon oxide, boron/phosphorous doped oxide, and the like. The dielectric layer is typically formed over various features, components, micro devices, or layers formed on or in the substrate. For example, the dielectric layer may be an interlayer dielectric, and which may have conductors formed therein to provide conductive paths with vias extending to conductors lying below and above the dielectric layer.

At block 30, a barrier layer is formed to line the opening(s) e.g., using a conventional method such as chemical vapor deposition (CVD) or physical vapor deposition (PVD). In some embodiments, the barrier layer may also cover a top surface of the dielectric layer or the field area of the device. The barrier layer may be used when a material to be subsequently deposited in openings is susceptible to diffusion into the dielectric layer, such as copper and copper alloys. The barrier layer may be less than 100 angstroms (Å) thick, in some embodiments. In other embodiments, a barrier layer may be less than 10 Å. The barrier layer may be formed from, for example, one or more of tantalum (Ta), tantalum nitride (TaN), tantalum silicon nitride (TaSiN), tantalum carbonate nitride (TaCN), tantalum carbonide (TaC), titanium (Ti), titanium nitride (TiN), titanium silicon nitride (TiSiN), tungsten (W), tungsten nitride (WN), tungsten carbonate nitride (WCN), etc., and nitrides, oxides, and alloys thereof.

At block 40, a conductive seed layer (e.g., a copper seed layer) may be formed over the barrier layer. This seed layer may line the opening, and optionally the top surface of the dielectric layer or the field area. In one embodiment, the seed layer may have a thickness of less than 60 Å, optimally, less than 45 Å, and even less than 20 Å. In one embodiment, the conductive material for the seed layer is copper or copper alloy. The seed layer is deposited to carry the electrical current for the electroplating of the copper. The seed layer can also be formed from nickel, gold, or other materials.

Referring still to FIG. 1, at block 50, a conductive material (e.g., copper) is deposited or plated into the opening to fill the opening(s). The conductive material can be deposited using electroplating or electroless plating, in some embodiments. Thus after this forming process, incoming step heights of the topographical features may be in the range of approximately 0.1-0.2 microns. At block 60, the conductive material is planarized. More specifically, electropolishing may be performed to remove the conductive material down to a predetermined thickness (i.e., in the field areas, ideally to zero thickness in field areas). Note that this electropolishing process may be performed while the wafer is ultrasonically agitated. For example, a transducer may be powered to provide ultrasonic agitation during this phase of electropolishing. Finally, the barrier layer not formed in the opening(s) (i.e., that is formed in the field areas) may be removed (block 70). The barrier layer can be removed using a dry etching process with Freon or other suitable etch methods. While shown with this particular implementation in the embodiment of FIG. 1, the scope of the present invention is not limited in this regard.

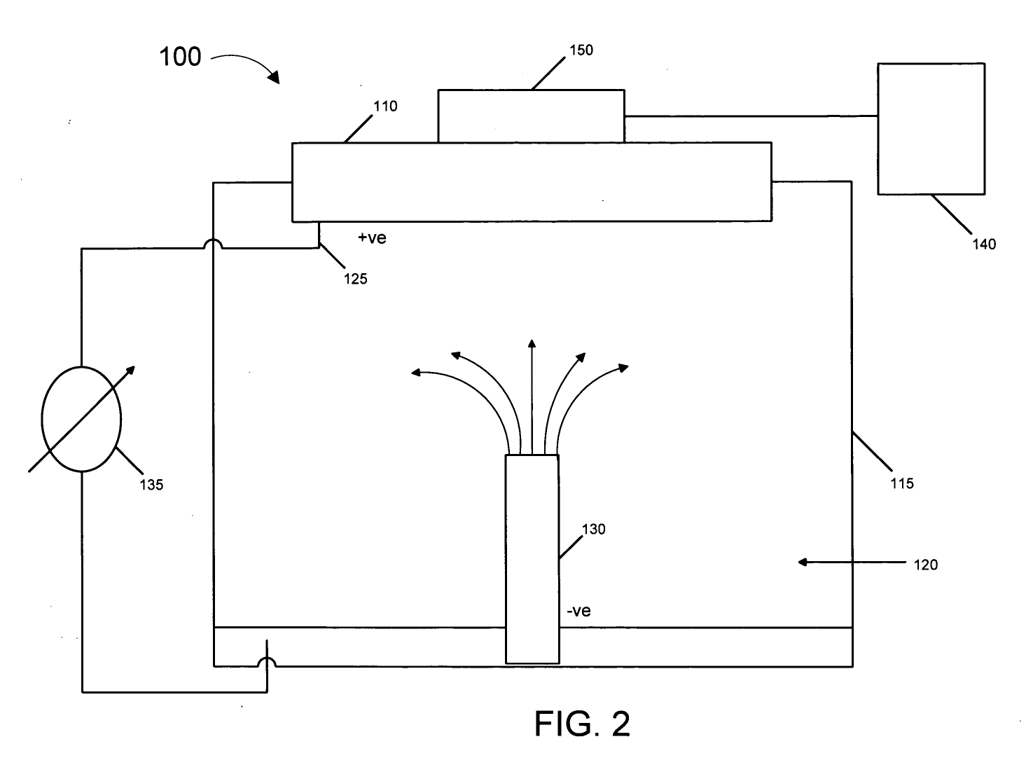

Referring now to FIG. 2, shown is a block diagram of a semiconductor tool in accordance with an embodiment of the present invention. As shown in FIG. 2, tool 100 may be used to perform electropolishing of a wafer 110. Tool 100 may include a vessel 115 having an electrolytic solution 120 in which the electropolishing is performed. Tool 100 may be an immersed wafer type reactor. An anode 125 may be coupled to semiconductor wafer 110, which has a frontside immersed in electrolytic solution 120.

A power supply 135, which may be a current (or voltage) controlled power supply, may set up a voltage difference between anode 125, which may be at a positive voltage, e.g., +Vₑ and a cathode 130, which may be at a negative voltage, e.g., −Vₑ so that the conductive material may be pulled or planarized from wafer 110.

In one embodiment, the electropolishing process is performed by polarizing a metal surface anodically in a phosphoric acid solution. In this embodiment, a phosphoric acid based electropolish chemistry may contain less than 57% phosphoric acid, less than 43% glycerine, and less than 10% water. The electropolishing solution may also include additional additives such as water, glycerin, butanol, ethylene glycol, etc.

Note that in the embodiment of FIG. 2, an additional power supply 140 is present and may be used to provide power to a transducer 150. Transducer 150 may be coupled to wafer 110 such that it may cause vibration of the wafer. Such vibration may be at ultrasonic frequencies to enable improved electropolishing. In some embodiments, the electropolishing may occur while wafer 110 is agitated at a frequency greater than approximately 10 kilohertz (kHz). At these frequencies, ultrasonic agitation decreases the diffusion boundary layer thickness of the electrolytic solution. That is, in typical solutions without ultrasonic agitation, typical boundary layer thickness is approximately 10 microns. At this thickness, there may be insufficient difference in metal removal rates between protrusions on wafer surface versus depressions to achieve target planarization. Accordingly, the boundary layer should be thinner to achieve target planarization rates. Using ultrasonic agitation, a boundary layer may have a thickness of 1 micron or less, allowing for efficient planarization.

By electropolishing in accordance with one embodiment, conventional CMP processing to reduce incoming within die (WID) thickness variation and local roughness may be avoided. In this way, the significant cost increases associated with CMP may be avoided. Furthermore, the mechanical forces created by CMP (e.g., from 2-4 pounds per square inch) can be avoided. Accordingly, embodiments may eliminate mechanical defects such as delaminations, bent lines, and scratches of Cu lines and low-k ILDs. Furthermore, ultra-low k ILD integration and line size scaling of interconnects may be enabled.

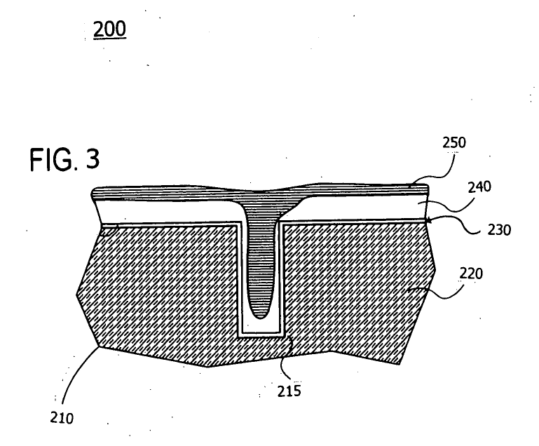

Referring now to FIG. 3, shown is a cross section view of a semiconductor wafer in accordance with an embodiment of the present invention. As shown in FIG. 3, a wafer 200 includes a substrate 210. During processing, a dielectric layer 220 may be formed. Then an opening 215 may be formed in the dielectric layer. Such an opening may correspond to a trench or via to be filled with a conductive material for use as interconnect, for example.

Still referring to FIG. 3, a barrier layer 230 may be formed over dielectric layer 220. Then a seed layer 240 may be formed over barrier layer 230. Finally, a conductive material 250, which may be electroplated Cu, may be deposited. In this way, opening 215 is filled with a desired conductive material. Then, planarizing in accordance with an embodiment of the present invention may be performed to remove conductive material 250, barrier layer 240 and seed layer 230 from the field areas, while retaining the conductive material within opening 215. While shown with this particular implementation in the embodiment of FIG. 3, the scope of the present invention is not limited in this regard.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a dielectric layer on a semiconductor wafer and patterning at least one opening in the dielectric layer, the at least one opening surrounded by a field area;
depositing a barrier layer over the dielectric layer;
depositing a conductive layer over the barrier layer, wherein the conductive layer fills the at least one opening; and
electropolishing the conductive layer while ultrasonically agitating the semiconductor wafer until a predetermined amount of the conductive layer remains over the barrier layer.

2. The method of claim 1, further comprising electropolishing the conductive layer in a reactor including a cathode electrode, wherein the semiconductor wafer is coupled to an anode electrode.

3. The method of claim 2, further comprising applying an anodic current to the semiconductor wafer to electropolish the conductive layer,

4. The method of claim 3, further comprising reducing a boundary layer thickness of the electrolyte solution by ultrasonically agitating the semiconductor wafer at greater than approximately 10 kilohertz.

5. The method of claim 4, further comprising removing the barrier layer from the field area.

6. The method of claim 4, wherein the electrolyte solution includes phosphoric acid and glycerin.

7. The method of claim 4, further comprising depositing the conductive layer by electroplating a copper material over a seed layer formed over the barrier layer.

8. An apparatus comprising:
a vessel to hold an electrolyte solution for use in electropolishing a conductive layer on a semiconductor wafer;
a cathode electrode for placement in the electrolyte solution;
a first power supply to develop a potential difference between the cathode electrode and the semiconductor wafer;
a transducer to provide ultrasonic agitation to the semiconductor wafer during at least a portion of the electropolishing; and
a second power supply to provide power to the transducer.

9. The apparatus of claim 8, wherein the semiconductor wafer is to be located between the transducer and the cathode electrode.

10. The apparatus of claim 8, wherein the first power supply comprises a current or potential controlled power supply.

11. The apparatus of claim 8, wherein the transducer is to agitate the semiconductor wafer at greater than 10 kilohertz to reduce a diffusion boundary layer thickness of the electrolyte solution.
